(19) United States
(12) Patent Application Publication
(10) Pub. No.: US 2025/0150043 A1
(43) Pub. Date: May 8, 2025

(54) POWER AMPLIFIER CIRCUIT

(71) Applicant: MURATA MANUFACTURING CO., LTD., Kyoto (JP)

(72) Inventor: Makoto TABEI, Kyoto (JP)

(21) Appl. No.: 18/926,642

(22) Filed: Oct. 25, 2024

(30) Foreign Application Priority Data
Nov. 2, 2023 (JP) 2023-188692

(51) Int. Cl. H03F 3/21

(52) U.S. Cl. CPC H03F 3/21

(57) ABSTRACT

A power amplifier circuit includes: a first switch circuit that switches conduction and non-conduction between a node between the drive stage amplifier and the power stage amplifier and an output terminal, and a second switch circuit that switches conduction and non-conduction between the power stage amplifier and the output terminal. The power amplifier circuit has a first mode in which the first switch circuit is made conductive and the second switch circuit is made non-conductive, and a second mode in which the first switch circuit is made non-conductive and the second switch circuit is made conductive. The power amplifier circuit makes, when shifting from the first mode to the second mode, the first switch circuit non-conductive after making the second switch circuit conductive, and makes, when shifting from the second mode to the first mode, the second switch circuit non-conductive after making the first switch circuit conductive.

### CROSS REFERENCE TO RELATED APPLICATION

This application claims priority from Japanese Patent Application No. 2023-188692 filed on Nov. 2, 2023. The content of this application is incorporated herein by reference in its entirety.

### BACKGROUND

The present disclosure relates to a power amplifier circuit.

Conventionally, in a power amplifier circuit used for wireless communication or the like, a technique for switching operation mode according to the magnitude of the output power is disclosed (see, for example, Japanese Unexamined Patent Application Publication (Translation of PCT Application) No. 2006-512847). As an example of a method of switching operation mode, Japanese Unexamined Patent Application Publication (Translation of PCT Application) No. 2006-512847 illustrates a configuration in which a bypass switching circuit is provided to bypass a power stage amplifier when a low output power is required.

### BRIEF SUMMARY

In a configuration in which a high frequency signal path is switched using a bypass switching circuit, the high frequency signal path may be cut off depending on the switching timing, resulting in a gain drop. Further, when switching from a low power mode to a high power mode, overshoot may occur, and it may take time to stabilize the gain after the mode switching. Such gain fluctuation caused by the switching of the operation mode may cause a communication error.

The present disclosure realizes a power amplifier circuit capable of suppressing gain fluctuation caused by the switching of the operation mode.

A power amplifier circuit according to an aspect of the present disclosure is a power amplifier circuit having a two-stage configuration in which a drive stage amplifier and a power stage amplifier are connected in series, the power amplifier circuit including: a first switch circuit that switches conduction and non-conduction between a node between the drive stage amplifier and the power stage amplifier and an output terminal; and a second switch circuit that switches conduction and non-conduction between the power stage amplifier and the output terminal, wherein the power amplifier circuit has a first mode in which the first switch circuit is made conductive and the second switch circuit is made non-conductive, and a second mode in which the first switch circuit is made non-conductive and the second switch circuit is made conductive, and the power amplifier circuit makes, when shifting from the first mode to the second mode, the first switch circuit non-conductive after making the second switch circuit conductive, and makes, when shifting from the second mode to the first mode, the second switch circuit non-conductive after making the first switch circuit conductive.

Thus, with such a configuration, it is possible to suppress gain fluctuation caused by the switching of the operation mode.

According to the present disclosure, it is possible to realize a power amplifier circuit capable of suppressing gain fluctuation caused by the switching of the operation mode.

### BRIEF DESCRIPTION OF THE DRAWINGS

FIG. 1 is a diagram showing a configuration of a power amplifier circuit according to an embodiment;

FIG. 2 is a timing chart showing an example of control timing in a conventional example;

FIG. 3A is a diagram showing a control state of switching elements in LPM;

FIG. 3B is a diagram showing a control state of the switching elements in HPM;

FIG. 4 is a diagram showing a configuration example of the switching elements;

FIG. 5A is a diagram showing an operational example of switching elements during a transition from LPM to HPM in the conventional example;

FIG. 5B is a diagram showing an operational example of the switching elements during a transition from HPM to LPM in the conventional example;

FIG. 6 is a conceptual diagram showing an example of a gain fluctuation during a transition from LPM to HPM in the conventional example;

FIG. 7 is a timing chart showing an example of control timing of the power amplifier circuit according to the embodiment;

FIG. 8 is a block diagram showing an example of an internal configuration of a control circuit;

FIG. 9A is a first diagram showing an operational example of the switching elements during mode transition in the power amplifier circuit according to the embodiment;

FIG. 9B is a second diagram showing an operational example of the switching elements during mode transition in the power amplifier circuit according to the embodiment;

FIG. 10 is a timing chart showing an example of control timing of a power amplifier circuit according to a comparative example;

FIG. 11A is a diagram showing an operational example of switching elements during a transition from LPM to HPM in the comparative example;

FIG. 11B is a diagram showing a loop path during mode transition in the power amplifier circuit according to the embodiment; and

FIG. 12 is a timing chart showing an example of control timing of a power amplifier circuit according to a variation of the embodiment.

### DETAILED DESCRIPTION

A power amplifier circuit according to an embodiment will be described below in detail with reference to the drawings. Note that the present disclosure is not limited by the embodiments. Each embodiment is an example; and it is needless to say that partial replacement or combination of the configurations shown in the different embodiments is possible. In a variation of the embodiment, the description of matters common to Embodiment 1 will be omitted, and only different points will be described. In particular, similar effects by similar configurations will not be referred to one by one in each embodiment.

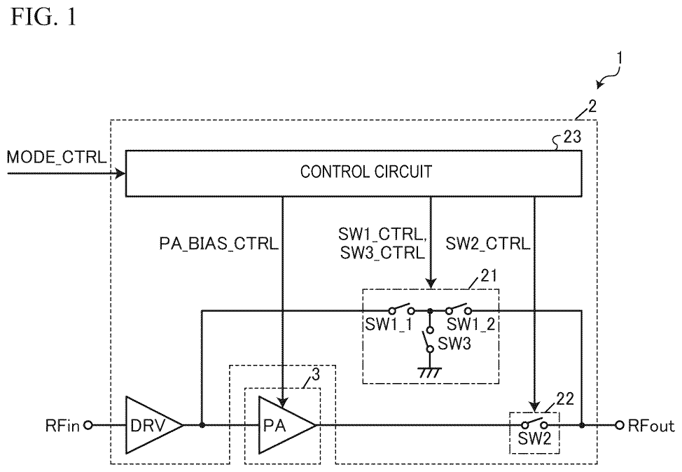

FIG. 1 is a diagram showing a configuration of the power amplifier circuit according to the embodiment. A power amplifier circuit 1 shown in FIG. 1 is a two-stage RF power amplifier in which a drive stage amplifier DRV and a power stage amplifier PA are connected in series. The power amplifier circuit 1 amplifies a high frequency signal input from an input terminal RFin and outputs the amplified high frequency signal from an output terminal RFout. Although not shown in the drawings, matching circuits are provided at an input end of the power amplifier circuit, at an output end of the power amplifier circuit, and between the drive stage amplifier DRV and the power stage amplifier PA, respectively.

The power amplifier circuit 1 according to the embodiment has, as operation modes, a low power mode (hereinafter also referred to as “LPM”) operating at a relatively low output power and a high power mode (hereinafter also referred to as “HPM”) operating at a relatively high output power. In the present disclosure, the low power mode (LPM) corresponds to a first mode. Also, in the present disclosure, the high power mode (HPM) corresponds to a second mode.

The power amplifier circuit 1 includes, as components for switching operation modes, a first switch circuit 21, a second switch circuit 22, and a control circuit 23.

The first switch circuit 21 switches conduction and non-conduction between a node between the drive stage amplifier DRV and the power stage amplifier PA and the output terminal RFout.

The first switch circuit 21 includes first switching elements SW1_1 and SW1_2, and a third switching element SW3. The first switching elements SW1_1 and SW1_2 are connected in series between the node between the drive stage amplifier DRV and the power stage amplifier PA and the output terminal RFout. The third switching element SW3 is shunted connected between a node between the first switching elements SW1_1 and SW1_2 and a ground potential.

The second switch circuit 22 switches conduction and non-conduction between the power stage amplifier PA and the output terminal RFout.

The second switch circuit 22 includes a second switching element SW2. The second switching element SW2 is connected in series between the power stage amplifier PA and the output terminal RFout.

In the present disclosure, the control circuit 23 performs on/off control of the first switching elements SW1_1 and SW1_2, the second switching element SW2, and the third switching element SW3. Further, in the present disclosure, the control circuit 23 performs bias control of the power stage amplifier PA.

In the configuration shown in FIG. 1, the drive stage amplifier DRV, the first switch circuit 21, the second switch circuit 22, and the control circuit 23 are composed of a silicon device (IC: integrated circuit) including a field effect transistor (FET) formed on, for example, a Si (silicon) substrate 2. The power stage amplifier PA is composed of an HBT device (IC: integrated circuit) including a heterojunction bipolar transistor (HBT) formed on, for example, a GaAs (gallium arsenide) substrate 3.

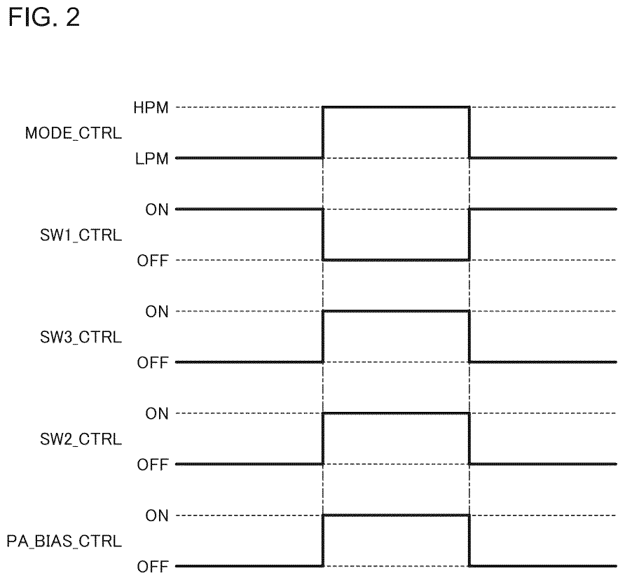

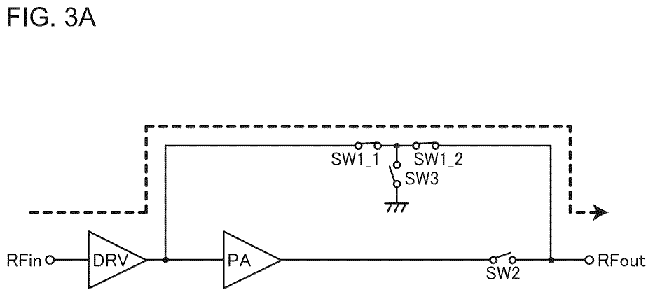

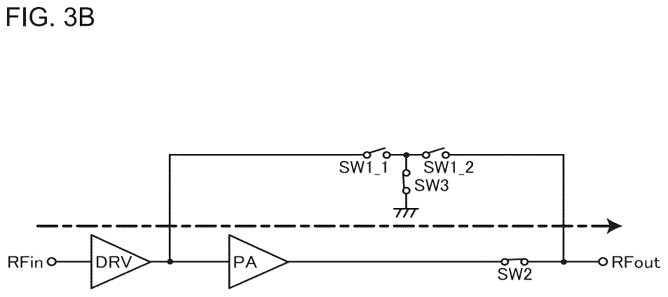

FIG. 2 is a timing chart showing an example of control timing in a conventional example. FIG. 3A is a diagram showing a control state of the switching elements in LPM. FIG. 3B is a diagram showing a control state of the switching elements in HPM.

In the present disclosure, an operation mode control signal MODE CTRL is inputted to the control circuit 23 from a host control system (not shown). The control circuit 23 performs switching control between LPM and HPM based on the operation mode control signal MODE CTRL.

Specifically, in LPM, as shown in FIG. 3A, the control circuit 23 on-controls the first switching elements SW1_1 and SW1_2, off-controls the second switching element SW2 and the third switching element SW3, and off-controls the bias of the power stage amplifier PA. Thus, a high frequency signal path indicated by a dashed line arrow is formed, and the high frequency signal amplified by the drive stage amplifier DRV is output from the output terminal RFout.

In HPM, as shown in FIG. 3B, the control circuit 23 off-controls the first switching elements SW1_1 and SW1_2, on-controls the second switching element SW2 and the third switching element SW3, and on-controls the bias of the power stage amplifier PA. Thus, a high frequency signal path indicated by a one-dot chain line arrow is formed, and the high frequency signal amplified by the drive stage amplifier DRV is further amplified by the power stage amplifier PA to be outputted from the output terminal RFout.

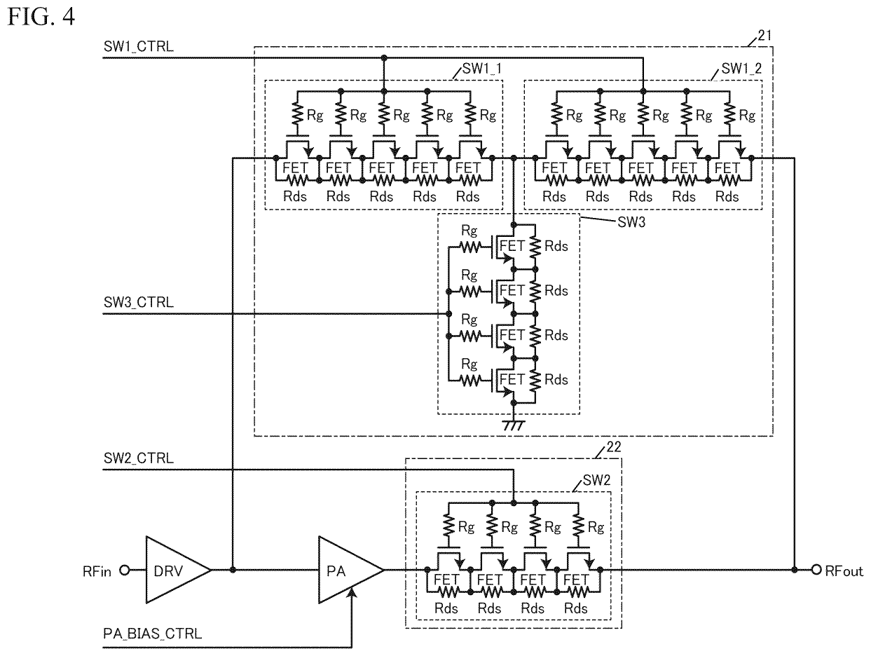

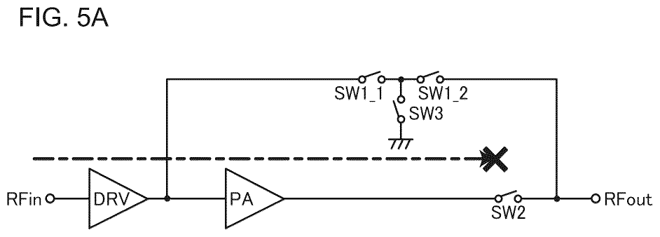

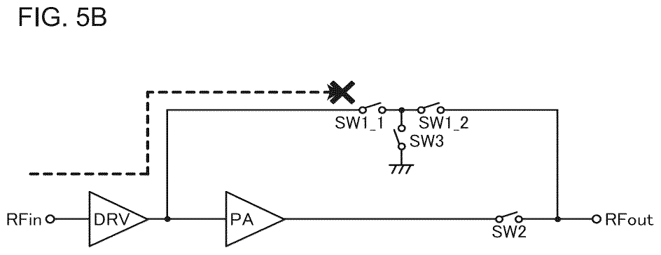

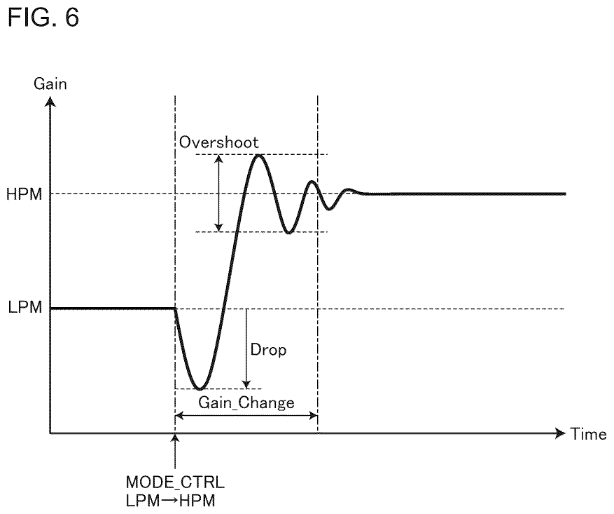

FIG. 4 is a diagram showing a configuration example of the switching elements. FIG. 5A is a diagram showing an operational example of switching elements during a transition from LPM to HPM in the conventional example. FIG. 5B is a diagram showing an operational example of the switching elements during a transition from HPM to LPM in the conventional example. FIG. 6 is a conceptual diagram showing an example of gain fluctuation during a transition from LPM to HPM in the conventional example.

As shown in FIG. 4, the first switching elements SW1_1 and SW1_2, the second switching element SW2, and the third switching element SW3 are each configured by connecting a plurality of FETs in series.

The timing at which the switching elements of an aspect shown in FIG. 4 are on-controlled to actually turn on is delayed with respect to the on-control timing. The delay amount is determined by the gate capacitance and the gate resistance corresponding to the size of the FET. On the other hand, the delay amount of the timing at which the switching elements of the aspect shown in FIG. 4 are off-controlled to actually turn off is smaller than the delay amount with respect to the on-control timing.

Therefore, in the timing chart of the conventional example shown in FIG. 2, for example, during the transition from LPM to HPM, as shown in FIG. 5A, the on-timing of the second switching element SW2 is delayed with respect to the off-timing of the first switching elements SW1_1 and SW1_2, so that the high frequency signal path may be cut off. Also, for example, during the transition from HPM to LPM, as shown in FIG. 5B, the on-timing of the first switching elements SW1_1 and SW1_2 is delayed with respect to the off-timing of the second switching element SW2, so that the high frequency signal path may be cut off.

The gain change period Gain Change caused by the switching of the operation mode is specified as 500 ns to 2 μs, for example. FIG. 6 schematically shows an example in which, during the transition from LPM to HPM, the on-timing of the second switching element SW2 is delayed with respect to the off-timing of the first switching elements SW1_1 and SW1_2, and thereby the high frequency signal path is cut off, resulting in a gain drop. Also, FIG. 6 schematically shows an example in which an overshoot occurs when the second switching element SW2 is actually turned on, and the gain is not stabilized within the gain change period Gain Change caused by the switching of the operation mode. Such gain fluctuation caused by the switching of the operation mode may cause a communication error.

The switching timing of each switching element capable of suppressing gain fluctuation caused by the switching of the operation mode and a configuration capable of realizing such switching timing will be described below.

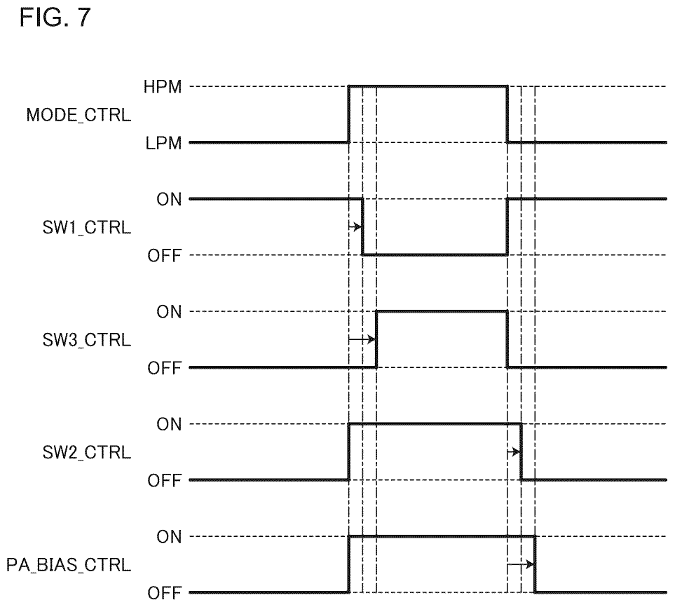

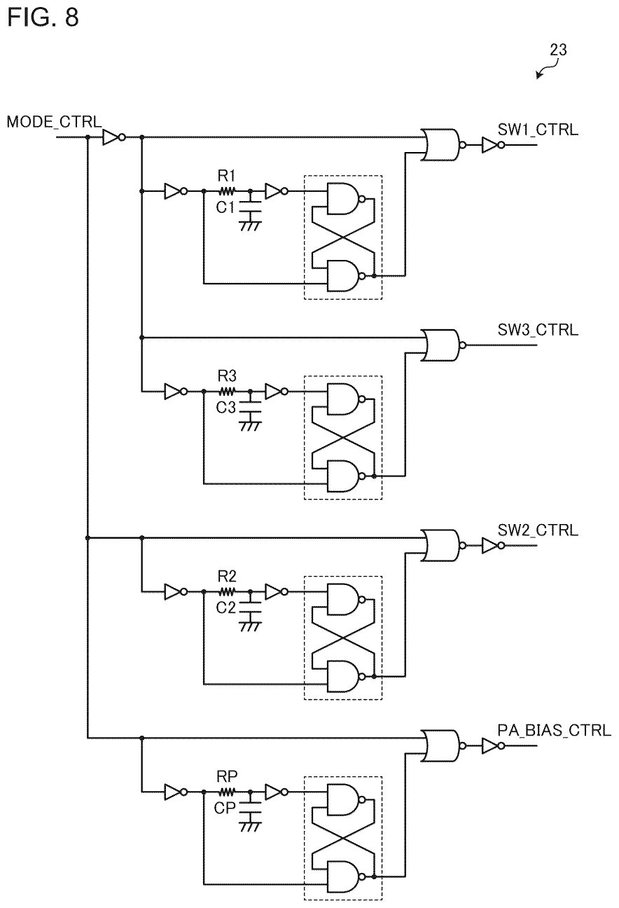

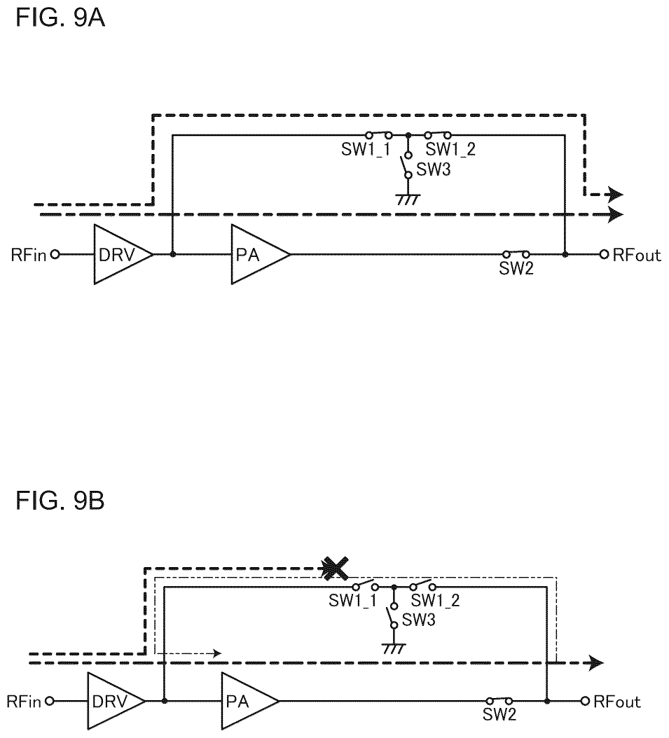

FIG. 7 is a timing chart showing an example of control timing of the power amplifier circuit according to the embodiment. FIG. 8 is a block diagram showing an example of an internal configuration of the control circuit. FIG. 9A is a first diagram showing an operational example of the switching elements during mode transition in the power amplifier circuit according to the embodiment. FIG. 9B is a second diagram showing an operational example of the switching elements during mode transition in the power amplifier circuit according to the embodiment.

As shown in FIG. 3A, in LPM, the first switching elements SW1_1 and SW1_2 are turned on, and the second switching element SW2 and the third switching element SW3 are turned off. When shifting from LPM to HPM, as shown in FIG. 7, the control circuit 23 on-controls the second switching element SW2 and on-controls the bias of the power stage amplifier PA before off-controlling the first switching elements SW1_1 and SW1_2. In other words, when shifting from LPM to HPM, the control circuit 23 delays the off-control timing of the first switching elements SW1_1 and SW1_2 with respect to the on-control timing of the second switching element SW2. In the configuration shown in FIG. 8, the off-control timing delay amount of the first switching elements SW1_1 and SW1_2 can be set by a R1C1 circuit shown in FIG. 8 with respect to the switching timing of the operation mode control signal MODE_CTRL from LPM to HPM.

When the second switching element SW2 is on-controlled, as shown in FIG. 9A, both a high frequency signal path (dashed line) for LPM and a high frequency signal path (one-dot chain line) for HPM are formed. Thereafter, the first switching elements SW1_1 and SW1_2 are off-controlled, as shown in FIG. 9B, and thereby the high frequency signal path (dashed line) for LPM is cut off.

In the state shown in FIG. 9B, a loop path (two-dot chain line) of the high frequency signal of HPM may be formed by the capacitance components of the first switching elements SW1_1 and SW1_2, so that good reverse isolation cannot be obtained.

Therefore, the control circuit 23 on-controls the third switching element SW3 after off-controlling the first switching elements SW1_1 and SW1_2. That is, the control circuit 23 delays the on-control timing of the third switching element SW3 with respect to the off-control timing of the first switching elements SW1_1 and SW1_2. Thus, good reverse isolation in HPM can be maintained. In the configuration shown in FIG. 8, the on-control timing delay amount of the third switching element SW3 can be set by a R3C3 circuit shown in FIG. 8 with respect to the switching timing of the operation mode control signal MODE_CTRL from LPM to HPM.

When the third switching element SW3 is on-controlled, the capacitance components of the first switching elements SW1_1 and SW1_2 are grounded, so that the control state of the switching elements becomes the control state of the switching elements in HPM shown in FIG. 3B, in which the high frequency signal amplified by the drive stage amplifier DRV is further amplified by the power stage amplifier PA and outputted from the output terminal RFout.

As shown in FIG. 3B, in HPM, the first switching elements SW1_1 and SW1_2 are turned off, and the second switching element SW2 and the third switching element SW3 are turned on. When shifting from HPM to LPM, as shown in FIG. 7, the control circuit 23 on-controls the first switching elements SW1_1 and SW1_2 and off-controls the third switching element SW3 before off-controlling the second switching element SW2. In other words, when shifting from HPM to LPM, the control circuit 23 delays the off-control timing of the second switching element SW2 with respect to the on-control timing of the first switching elements SW1_1 and SW1_2. In the configuration shown in FIG. 8, the off-control timing delay amount of the second switching element SW2 can be set by a R2C2 circuit shown in FIG. 8 with respect to the switching timing of the operation mode control signal MODE_CTRL from HPM to LPM.

When the first switching elements SW1_1 and SW1_2 are on-controlled and the third switching element SW3 is off-controlled, as shown in FIG. 9A, both the high frequency signal path (dashed line) for LPM and the high frequency signal path (one-dot chain line) for HPM are formed. Thereafter, the second switching element SW2 is off-controlled, and thereby the control state of the switching elements becomes the control state of switching elements in LPM shown in FIG. 3A. Thereafter, the control circuit 23 off-controls the bias of the power stage amplifier PA. Thus, the high frequency signal amplified by the drive stage amplifier DRV is output from the output terminal RFout. In the configuration shown in FIG. 8, the off-control timing delay amount of the bias of the power stage amplifier PA can be set by a RPCP circuit shown in FIG. 8 with respect to the switching timing of the operation mode control signal MODE_CTRL from HPM to LPM.

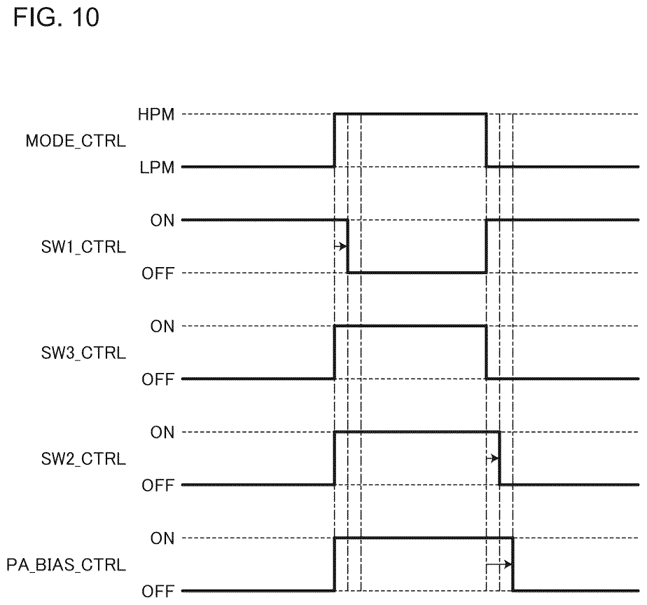

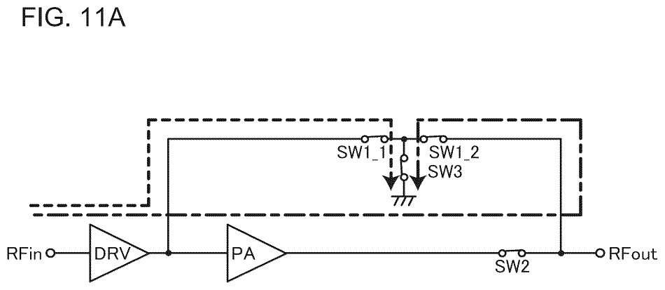

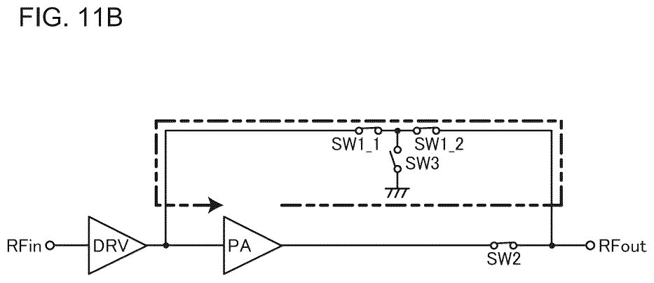

FIG. 10 is a timing chart showing an example of control timing of a power amplifier circuit according to a comparative example. FIG. 11A is a diagram showing an operational example of switching elements during a transition from LPM to HPM in the comparative example.

The comparative example shown in FIG. 10 shows an example in which, when shifting from LPM to HPM, the third switching element SW3 is on-controlled before the first switching elements SW1_1 and SW1_2 are off-controlled. In such a case, as shown in FIG. 11A, a short-circuit path to the ground potential is formed in both a high frequency signal path (dashed line) for LPM and a high frequency signal path (one-dot chain line) for HPM.

FIG. 11B is a diagram showing a loop path during mode transition in the power amplifier circuit according to the embodiment. As shown in FIG. 9A, when both the high frequency signal path (dashed line) for LPM and the high frequency signal path (one-dot chain line) for HPM are formed, a loop path indicated by a two-dot chain line arrow in FIG. 11B is formed. The phase of the loop path changes according to the impedance of the circuit, and the loop path may become a positive feedback loop, causing oscillation of the power stage amplifier PA.

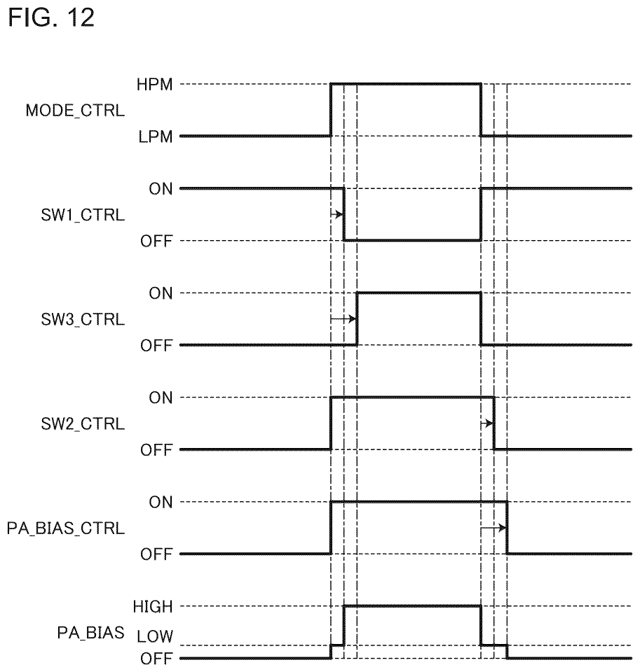

FIG. 12 is a timing chart showing an example of control timing of a power amplifier circuit according to a variation of the embodiment.

In the timing chart shown in FIG. 12, the bias of the power stage amplifier PA is set to a low bias (LOW) lower than a normal bias (HIGH) in HPM in a period from the on-control timing of the bias of the power stage amplifier PA to the off-control timing of the first switching elements SW1_1 and SW1_2 during the shift from LPM to HPM, and in a period from the on-control timing of the first switching elements SW1_1 and SW1_2 to the off-control timing of the bias of the power stage amplifier PA during the shift from HPM to LPM. Thus, oscillation of the power stage amplifier PA can be prevented when a loop path is formed. The embodiments described above are intended to facilitate understanding of the present disclosure, and are not intended to limit the interpretation of the present disclosure. The present disclosure may be changed/modified without necessarily departing from its scope, and the present disclosure also includes equivalents thereof.

The present disclosure may have the following configurations as described above or in lieu of the above.

(1) A power amplifier circuit according to an aspect of the present disclosure is a power amplifier circuit having a two-stage configuration in which a drive stage amplifier and a power stage amplifier are connected in series, the power amplifier circuit comprising: a first switch circuit that switches conduction and non-conduction between a node between the drive stage amplifier and the power stage amplifier and an output terminal; and a second switch circuit that switches conduction and non-conduction between the power stage amplifier and the output terminal, wherein the power amplifier circuit has a first mode in which the first switch circuit is made conductive and the second switch circuit is made non-conductive, and a second mode in which the first switch circuit is made non-conductive and the second switch circuit is made conductive, and the power amplifier circuit makes, when shifting from the first mode to the second mode, the first switch circuit non-conductive after making the second switch circuit conductive, and makes, when shifting from the second mode to the first mode, the second switch circuit non-conductive after making the first switch circuit conductive.

With such a configuration, when shifting from the first mode to the second mode, it is possible to prevent a case where the first switch circuit and the second switch circuit both become non-conductive. Also, when shifting from the second mode to the first mode, it is possible to prevent a case where the first switch circuit and the second switch circuit both become non-conductive. Thus, it is possible to suppress gain fluctuation caused by the switching of the operation mode.

(2) In the power amplifier circuit according to above (1), the first switch circuit at least includes a first switching element connected in series between the node between the drive stage amplifier and the power stage amplifier and the output terminal, the second switch circuit includes a second switching element connected in series between the power stage amplifier and the output terminal, the power amplifier circuit further comprises a control circuit that at least performs on/off control of the first switching element and the second switching element, and the control circuit off-controls, when shifting from the first mode to the second mode, the first switching element after on-controlling the second switching element, and off-controls, when shifting from the second mode to the first mode, the second switching element after on-controlling the first switching element.

With such a configuration, when shifting from the first mode to the second mode, it is possible to prevent a case where the first switching element and the second switching element are both turned off. Also, when shifting from the second mode to the first mode, it is possible to prevent a case where the first switching element and the second switching element are both turned off. Thus, it is possible to suppress gain fluctuation caused by the switching of the operation mode.

(3) In the power amplifier circuit according to above (2), the first switch circuit has a plurality of first switching elements connected in series between the node between the drive stage amplifier and the power stage amplifier and the output terminal, and further includes a third switching element shunted connected between a node between the plurality of first switching elements and a ground potential, and the control circuit on-controls, when shifting from the first mode to the second mode, the third switching element after off-controlling the first switching elements, and on-controls, when shifting from the second mode to the first mode, the first switching elements and off-controls the third switching element.

With such a configuration, it is possible to prevent the third switching element from being turned on while the plurality of the first switching elements is in the ON state. Thus, it is possible to prevent the formation of a short-circuit path of the high frequency signal path to the ground potential.

(4) In the power amplifier circuit according to above (3), the control circuit on-controls, when shifting from the first mode to the second mode, the second switching element and on-controls a bias of the power stage amplifier, and off-controls, when shifting from the second mode to the first mode, the bias of the power stage amplifier after off-controlling the second switching element.

(5) In the power amplifier circuit according to above (4), when shifting from the first mode to the second mode, the control circuit on-controls the second switching element, and sets the bias of the power stage amplifier to a low bias lower than the bias of the power stage amplifier in the second mode during a period from an on-control timing of the bias of the power stage amplifier to an off-control timing of the first switching elements, and when shifting from the second mode to the first mode, the control circuit sets the bias of the power stage amplifier to the low bias during a period from an on-control timing of the first switching elements to an off-control timing of the bias of the power stage amplifier.

In such a configuration, the oscillation of the power stage amplifier can be suppressed when both the first switching elements and the second switching element are turned on, the phase changes according to the impedance, and thereby a positive feedback loop is formed.

(6) In the power amplifier circuit according to any one of above (1) to (5), the drive stage amplifier is a silicon device formed on a Si substrate, and the power stage amplifier is an HBT device formed on a GaAs substrate.

In such a configuration, the drive stage amplifier, a first bias circuit, and a second bias circuit can be integrally formed on the Si substrate. Further, the influence of heat generated by the power stage amplifier on the drive stage amplifier can be suppressed.

According to the present disclosure, it is possible to realize a power amplifier circuit capable of suppressing gain fluctuation caused by the switching of the operation mode.

What is claimed is:

1. A power amplifier circuit configured as a two-stage amplifier comprising a drive stage amplifier and a power stage amplifier connected in series, the two-stage power amplifier circuit comprising:
a first switch circuit configured to switch conduction and non-conduction between a first node and an output terminal, the first node being between the drive stage amplifier and the power stage amplifier; and
a second switch circuit configured to switch conduction and non-conduction between the power stage amplifier and the output terminal,
wherein the two-stage power amplifier circuit is configured to operate in a first mode in which the first switch circuit is conductive and the second switch circuit is non-conductive, and a second mode in which the first switch circuit is non-conductive and the second switch circuit is conductive,
wherein when shifting from the first mode to the second mode, the first switch circuit is configured to become non-conductive after the second switch circuit becomes conductive, and
wherein when shifting from the second mode to the first mode, the second switch circuit is configured to become non-conductive after the first switch circuit becomes conductive.

2. The power amplifier circuit according to claim 1, further comprising a control circuit configured to perform on/off control of a first switch and a second switch,
wherein the first switch circuit comprises the first switch connected in series between the first node and the output terminal,
wherein the second switch circuit comprises the second switch connected in series between the power stage amplifier and the output terminal, and
wherein the control circuit is configured to switch off the first switch after switching on the second switch when shifting from the first mode to the second mode, and is configured to switch off the second switch after switching on the first switch when shifting from the second mode to the first mode.

3. The power amplifier circuit according to claim 2,
wherein the first switch circuit comprises a plurality of first switches connected in series between the first node and the output terminal, and comprises a third switch that is shunt connected between a second node and a ground potential, the second node being between the plurality of first switching elements, and
wherein the control circuit is configured to switch on the third switch after switching off the first switch when shifting from the first mode to the second mode, and is configured to switch on the plurality of first switches and switch off the third switch when shifting from the second mode to the first mode.

4. The power amplifier circuit according to claim 3, wherein the control circuit is configured to switch on the second switch and switch on a bias of the power stage amplifier when shifting from the first mode to the second mode, and is configured to switch off the bias of the power stage amplifier after switching off the second switch when shifting from the second mode to the first mode.

5. The power amplifier circuit according to claim 4,
wherein, when shifting from the first mode to the second mode, the control circuit is configured to switch on the second switch and set the bias of the power stage amplifier to a lower bias than the bias of the power stage amplifier in the second mode during a period starting from switching on the bias of the power stage amplifier to switching off the first switching elements the control circuit is configured to switch on the second switch and set the bias of the power stage amplifier to a low bias that is lower than the bias of the power stage amplifier in the second mode between a time when the bias of the power stage amplifier is switched on and a time when the plurality of first switches is switched off, and
wherein, when shifting from the second mode to the first mode, the control circuit is configured to set the bias of the power stage amplifier to the low between a time when the plurality of first switches is switched on and the bias of the power stage amplifier is switched off.

6. The power amplifier circuit according to claim 1,
wherein the drive stage amplifier is a silicon device formed on a Si substrate, and
wherein the power stage amplifier is an HBT device formed on a GaAs substrate.

7. The power amplifier circuit according to claim 2,
wherein the drive stage amplifier is a silicon device formed on a Si substrate, and
wherein the power stage amplifier is an HBT device formed on a GaAs substrate.

8. The power amplifier circuit according to claim 3,
wherein the drive stage amplifier is a silicon device formed on a Si substrate, and
wherein the power stage amplifier is an HBT device formed on a GaAs substrate.

9. The power amplifier circuit according to claim 4,
wherein the drive stage amplifier is a silicon device formed on a Si substrate, and
wherein the power stage amplifier is an HBT device formed on a GaAs substrate.

10. The power amplifier circuit according to claim 5,
wherein the drive stage amplifier is a silicon device formed on a Si substrate, and
wherein the power stage amplifier is an HBT device formed on a GaAs substrate.
